(19) United States
(12) Patent Application Publication
(10) Pub. No.: US 2025/0287618 A1
(43) Pub. Date: Sep. 11, 2025

(54) CAPACITOR, INTEGRATED CIRCUIT, AND MANUFACTURING METHOD OF INTEGRATED CIRCUIT

(71) Applicant: Taiwan Semiconductor Manufacturing Company, Ltd., Hsinchu (TW)

(72) Inventors: Yi-Yang Wei, Hsinchu (TW); Bi-Shen Lee, Hsinchu (TW); Hai-Dang Trinh, Hsinchu (TW); Chung-Yi Yu, Hsin-Chu (TW)

(73) Assignee: Taiwan Semiconductor Manufacturing Company, Ltd., Hsinchu (TW)

(21) Appl. No.: 18/597,871

(22) Filed: Mar. 6, 2024

(51) Int. Cl. H01L 21/3205; H01L 27/06

(52) U.S. Cl. CPC H10D 1/68; H01L 21/3205; H10D 84/811

(57) ABSTRACT

A capacitor includes a first electrode, a second electrode over the first electrode, and a composite storage layer sandwiched between the first electrode and the second electrode. The composite storage layer includes a first storage layer and a second storage layer. The first storage layer is in physical contact with the first electrode. The second storage layer is in physical contact with the second electrode. A conduction band offset of the first storage layer is greater than a conduction band offset of the second storage layer, and a dielectric constant of the second storage layer is greater than a dielectric constant of the first storage layer.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an integrated circuit in accordance with some embodiments of the disclosure.

FIG. 2A to FIG. 2F are cross-sectional views illustrating various stages of a manufacturing method of the capacitor structure in FIG. 1 in accordance with some embodiments of the disclosure.

FIG. 3A is an enlarged view of a region in FIG. 2C in accordance with some embodiments of the disclosure.

FIG. 3B is an enlarged view of a region in FIG. 2C in accordance with some alternative embodiments of the disclosure.

FIG. 4 is a schematic cross-sectional view of an integrated circuit in accordance with some alternative embodiments of the disclosure.

FIG. 5A to FIG. 5F are cross-sectional views illustrating various stages of a manufacturing method of the capacitor structure in FIG. 4 in accordance with some embodiments of the disclosure.

FIG. 6A is an enlarged view of a region in FIG. 5D in accordance with some embodiments of the disclosure.

FIG. 6B is an enlarged view of a region in FIG. 5D in accordance with some alternative embodiments of the disclosure.

FIG. 7 is a schematic cross-sectional view of an integrated circuit in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

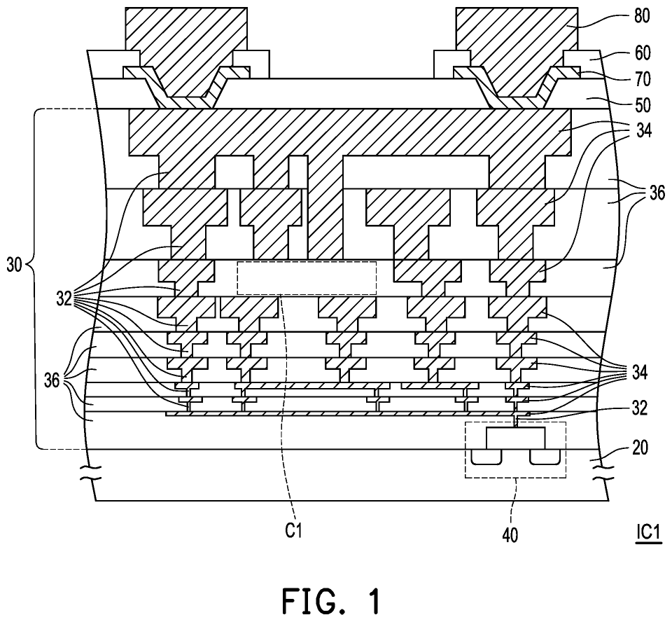

FIG. 1 is a schematic cross-sectional view of an integrated circuit IC1 in accordance with some embodiments of the disclosure. Referring to FIG. 1, the integrated circuit IC1 includes a substrate 20, an interconnect structure 30, a transistor 40, a passivation layer 50, a post-passivation layer 60, a plurality of conductive pads 70, and a plurality of conductive terminals 80. In some embodiments, the substrate 20 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 20 may be a bulk silicon substrate, a silicon-on-insulator (SOI) substrate, or a germanium-on-insulator (GOI) substrate.

In some embodiments, the substrate 20 includes various doped regions depending on circuit requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; and/or combinations thereof. In some embodiments, these doped regions serve as source/drain regions of the transistor 40, which is formed over the substrate 20. Throughout the disclosure, source/drain region(s) may refer to a source or a drain, individually or collectively dependent upon the context. Depending on the types of the dopants in the doped regions, the transistor 40 may be referred to as n-type transistor or p-type transistor. In some embodiments, the transistor 40 further includes a metal gate and a channel under the metal gate. The channel is located between the source region and the drain region to serve as a path for electrons to travel through when the transistor 40 is turned on. On the other hand, the metal gate is located above the substrate 20 and is embedded in the interconnect structure 30. In some embodiments, the transistor 40 is formed using suitable Front-end-of-line (FEOL) process. That is, the transistor 40 may be referred to as a FEOL transistor. For simplicity, one transistor 40 is shown in FIG. 1. However, it should be understood that more than one transistors 40 may be presented depending on the application of the integrated circuit IC1. When multiple transistors 40 are presented, these transistors 40 may be separated by shallow trench isolation (STI; not shown) located between two adjacent transistors 40. In some embodiments, the FEOL process may be further utilized to form other elements. For example, memory peripheral circuits, Static Random Access Memory (SRAM), and other computing circuits may be formed within/near the substrate 20 through the FEOL processes.

As illustrated in FIG. 1, the interconnect structure 30 is disposed on the substrate 20. In some embodiments, the interconnect structure 30 includes a plurality of conductive vias 32, a plurality of conductive patterns 34, a plurality of dielectric layers 36, and a capacitor structure C1. As illustrated in FIG. 1, the conductive patterns 34 and the conductive vias 32 are embedded in the dielectric layers 36. In some embodiments, the conductive patterns 34 located at different level heights are connected to one another through the conductive vias 32. In other words, the conductive patterns 34 are electrically connected to one another through the conductive vias 32. In some embodiments, the bottommost conductive vias 32 are connected to the transistor 40. For example, the bottommost conductive vias 32 are connected to the metal gate, which is embedded in the bottommost dielectric layer 36, of the transistor 40. In other words, the bottommost conductive vias 32 establish electrical connection between the transistor 40 and the conductive patterns 34 of the interconnect structure 30. It should be noted that in some alternative cross-sectional views, other bottommost conductive vias 32 are also connected to the source/drain regions of the transistor 40. That is, in some embodiments, the bottommost conductive vias 32 may be referred to as “contact structures” of the transistor 40.

In some embodiments, a material of the dielectric layers 36 includes polyimide, epoxy resin, acrylic resin, phenol resin, benzocyclobutene (BCB), polybenzooxazole (PBO), or any other suitable polymer-based dielectric material. Alternatively, the dielectric layers 36 may be formed of oxides or nitrides, such as silicon oxide, silicon nitride, aluminum oxide, hafnium oxide, hafnium zirconium oxide, or the like. In some embodiments, different dielectric layers 36 are formed by the same material. However, the disclosure is not limited thereto. In some alternative embodiments, different dielectric layers 36 may be formed by different materials. The dielectric layers 36 may be formed by suitable fabrication techniques, such as spin-on coating, chemical vapor deposition (CVD), plasma-enhanced chemical vapor deposition (PECVD), or the like.

In some embodiments, a material of the conductive patterns 34 and the conductive vias 32 includes aluminum, titanium, copper, nickel, tungsten, or alloys thereof. The conductive patterns 34 and the conductive vias 32 may be formed by electroplating, deposition, and/or photolithography and etching. In some embodiments, the conductive patterns 34 and the underlying conductive vias 32 are formed simultaneously. It should be noted that the number of the dielectric layers 36, the number of the conductive patterns 34, and the number of the conductive vias 32 illustrated in FIG. 1 are merely for illustrative purposes, and the disclosure is not limited thereto. In some alternative embodiments, fewer or more layers of the dielectric layers 36, the conductive patterns 34, and/or the conductive vias 32 may be formed depending on the circuit design.

As illustrated in FIG. 1, the passivation layer 50, the conductive pads 70, the post-passivation layer 60, and the conductive terminals 80 are sequentially formed on the interconnect structure 30. In some embodiments, the passivation layer 50 is disposed on the topmost dielectric layer 36 and the topmost conductive patterns 34. In some embodiments, the passivation layer 50 has a plurality of openings partially exposing each topmost conductive pattern 34. In some embodiments, the passivation layer 50 is a silicon oxide layer, a silicon nitride layer, a silicon oxynitride layer, or a dielectric layer formed by other suitable dielectric materials. The passivation layer 50 may be formed by suitable fabrication techniques, such as high-density-plasma chemical vapor deposition (HDP-CVD), PECVD, or the like.

In some embodiments, the conductive pads 70 are formed over the passivation layer 50. In some embodiments, the conductive pads 70 extend into the openings of the passivation layer 50 to be in physical contact with the topmost conductive patterns 34. That is, the conductive pads 70 are electrically connected to the interconnect structure 30. In some embodiments, the conductive pads 70 include aluminum pads, copper pads, titanium pads, nickel pads, tungsten pads, or other suitable metal pads. The conductive pads 70 may be formed by, for example, electroplating, deposition, and/or photolithography and etching. It should be noted that the number and the shape of the conductive pads 70 illustrated in FIG. 1 are merely for illustrative purposes, and the disclosure is not limited thereto. In some alternative embodiments, the number and the shape of the conductive pad 70 may be adjusted based on demand.

In some embodiments, the post-passivation layer 60 is formed over the passivation layer 50 and the conductive pads 70. In some embodiments, the post-passivation layer 60 is formed on the conductive pads 70 to protect the conductive pads 70. In some embodiments, the post-passivation layer 60 has a plurality of contact openings partially exposing each conductive pad 70. The post-passivation layer 60 may be a polyimide layer, a PBO layer, or a dielectric layer formed by other suitable polymers. In some embodiments, the post-passivation layer 60 is formed by suitable fabrication techniques, such as HDP-CVD, PECVD, or the like.

As illustrated in FIG. 1, the conductive terminals 80 are formed over the post-passivation layer 60 and the conductive pads 70. In some embodiments, the conductive terminals 80 extend into the contact openings of the post-passivation layer 60 to be in physical contact with the corresponding conductive pad 70. That is, the conductive terminals 80 are electrically connected to the interconnect structure 30 through the conductive pads 70. In some embodiments, the conductive terminals 80 are conductive pillars, conductive posts, conductive balls, conductive bumps, or the like. In some embodiments, a material of the conductive terminals 80 includes a variety of metals, metal alloys, or metals and mixture of other materials. For example, the conductive terminals 80 may be made of aluminum, titanium, copper, nickel, tungsten, tin, and/or alloys thereof. The conductive terminals 80 are formed by, for example, deposition, electroplating, screen printing, or other suitable methods. In some embodiments, the conductive terminals 80 are used to establish electrical connection with other components (not shown) subsequently formed or provided.

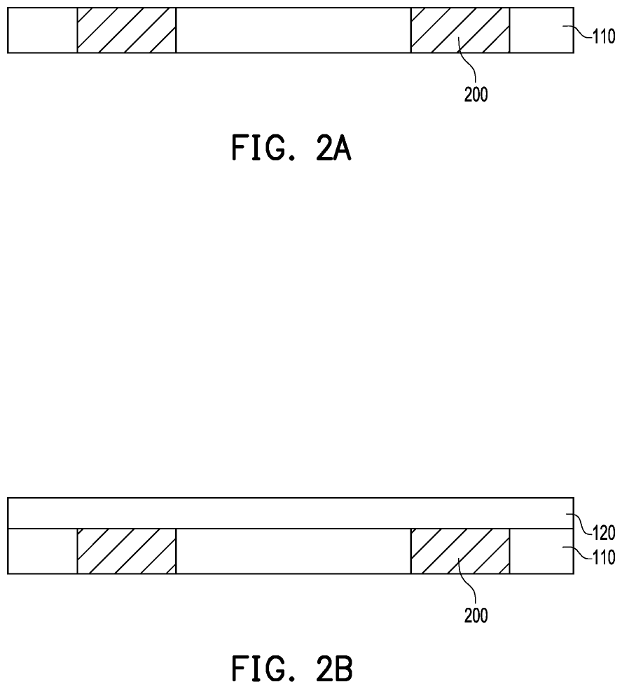

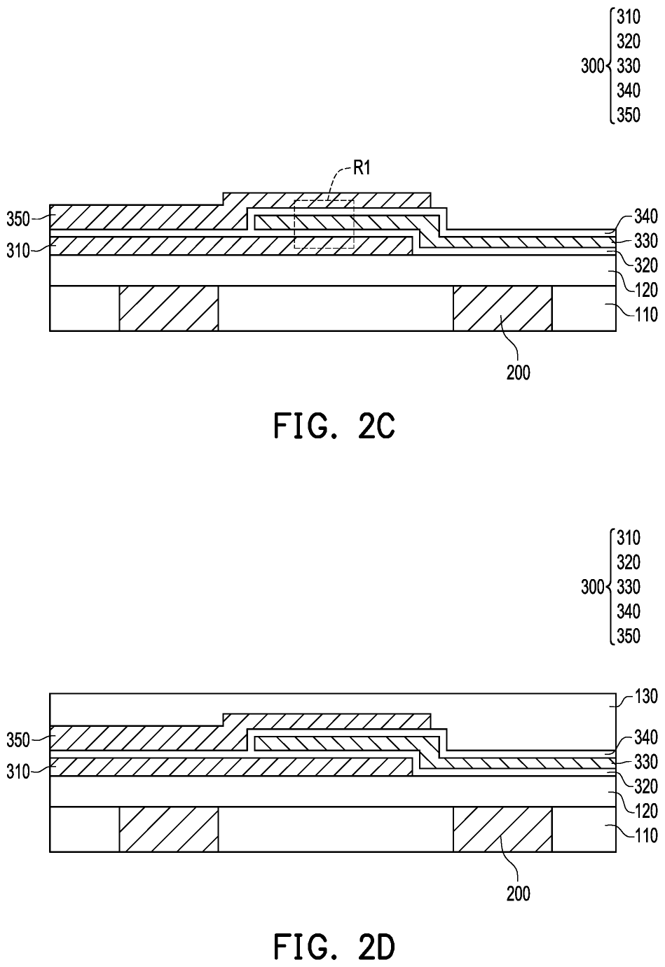

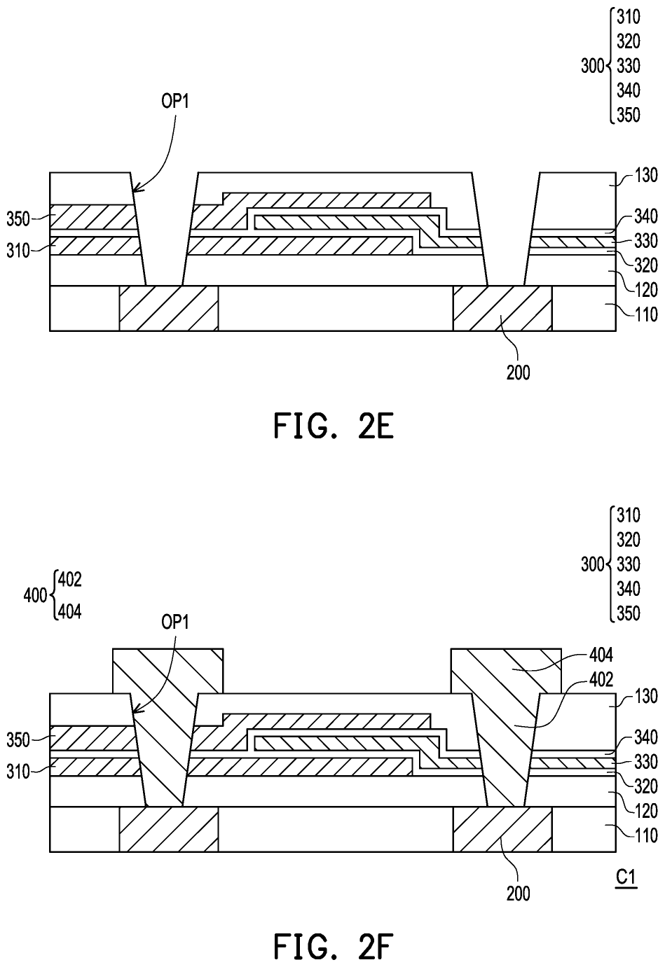

As illustrated in FIG. 1, the capacitor structure C1 is embedded in the interconnect structure 30. For example, the capacitor structure C1 is embedded in one of the dielectric layers 36. In some embodiments, the capacitor structure C1 is electrically connected to the underlying and overlaying conductive vias 32/conductive patterns 34. The formation method and the structure of the capacitor structure C1 will be described below in conjunction with FIG. 2A to FIG. 2F.

FIG. 2A to FIG. 2F are cross-sectional views illustrating various stages of a manufacturing method of the capacitor structure C1 in FIG. 1 in accordance with some embodiments of the disclosure. Referring to FIG. 2A, a sub-dielectric layer 110 is provided. In some embodiments, the sub-dielectric layer 110 is part of one of the dielectric layers 36 of the interconnect structure 30 in FIG. 1, so the detailed description thereof is omitted herein. In some embodiments, a plurality of conductive patterns 200 is formed in the sub-dielectric layer 110. For example, the conductive patterns 200 are embedded in the sub-dielectric layer 110. In some embodiments, the conductive patterns 200 are electrically connected to the conductive patterns 34 and the conductive vias 32 of the interconnect structure 30 in FIG. 1. In some embodiments, each of the conductive patterns 200 includes a seed layer and a metal layer on the seed layer. The seed layer may be a conformal layer lining sidewalls and a bottom surface of the metal layer. In some embodiments, the seed layer may be a single layer or a composite layer including a plurality of sub-layers formed of different materials. For example, the seed layer is a titanium/copper composited layer. The metal layer may include a metal material, such as Al, Cu, W, Co, Pd, Pt, Ni, other low resistivity metal constituent, an alloy thereof, or a combination thereof, and are formed by an electroplating process. As illustrated in FIG. 2A, a top surface of the sub-dielectric layer 110 and top surfaces of the conductive patterns 200 are coplanar.

Referring to FIG. 2B, a sub-dielectric layer 120 is formed on the sub-dielectric layer 110 and the conductive patterns 200. In some embodiments, the sub-dielectric layer 120 is part of one of the dielectric layers 36 of the interconnect structure 30 in FIG. 1. In some embodiments, a material and a formation method of the sub-dielectric layer 120 are similar to that of the sub-dielectric layer 110, so the detailed descriptions thereof are omitted herein.

Referring to FIG. 2C, a capacitor 300 is formed on the sub-dielectric layer 120. In some embodiments, the capacitor 300 includes an electrode 310, a composite storage layer 320, an electrode 330, a composite storage layer 340, and an electrode 350. In some embodiments, the capacitor 300 is formed by the following steps. First, a first electrode material layer (not shown) is conformally formed on a top surface of the sub-dielectric layer 120 by a suitable technique such as a physical vapor deposition (PVD) process or a plating process. Thereafter, the first electrode material layer is patterned by a photolithography and etching process to form the electrode 310. As illustrated in FIG. 2C, the electrode 310 covers a first portion of the sub-dielectric layer 120 and exposes a second portion of the sub-dielectric layer 120. After the electrode 310 is formed on the sub-dielectric layer 120, the composite storage layer 320 is conformally formed on the electrode 310 and the sub-dielectric layer 120. For example, the composite storage layer 320 covers the electrode 310 and the second portion of the sub-dielectric layer 120 that is exposed by the electrode 310. In some embodiments, the composite storage layer 320 is formed by, for example, CVD, PECVD, flowable chemical vapor deposition (FCVD), HDP-CVD, sub-atmospheric chemical vapor deposition (SACVD), PVD, or atomic layer deposition (ALD). Then, a second electrode material layer (not shown) is conformally formed on a top surface of the composite storage layer 320 by a suitable technique such as a PVD process or a plating process. Thereafter, the second electrode material layer is patterned by a photolithography and etching process to form the electrode 330. As illustrated in FIG. 2C, the electrode 330 covers a first portion of the composite storage layer 320 and exposes a second portion of the composite storage layer 320. After the electrode 330 is formed on the composite storage layer 320, the composite storage layer 340 is formed on the electrode 330. As illustrated in FIG. 2C, the composite storage layer 340 also exposes the second portion of the composite storage layer 320. In some embodiments, the composite storage layer 340 is formed by, for example, CVD, PECVD, FCVD, HDP-CVD, SACVD, PVD, or ALD. Subsequently, a third electrode material layer (not shown) is conformally formed on a top surface of the second portion of the composite storage layer 320 and a top surface of the composite storage layer 340 by a suitable technique such as a PVD process or a plating process. Lastly, the third electrode material layer is patterned by a photolithography and etching process to form the electrode 350. As illustrated in FIG. 2C, the electrode 350 covers the second portion of the composite storage layer 320 and a first portion of the composite storage layer 340. Meanwhile, the electrode 350 exposes a second portion of the composite storage layer 340.

As illustrated in FIG. 2C, the second portion of the composite storage layer 320 is in physical contact with both the electrode 310 and the electrode 350 to form a metal-insulator-metal (MIM) structure. Meanwhile, the first portion of the composite storage layer 320 is in physical contact with both the electrode 310 and the electrode 330 to form another MIM structure. Moreover, the composite storage layer 340 is in physical contact with both the electrode 330 and the electrode 350 to form yet another MIM structure. That is, the capacitor 300 may be referred to as a MIM capacitor. In some embodiments, the composite storage layers 320 and 340 are utilized to store capacitance.

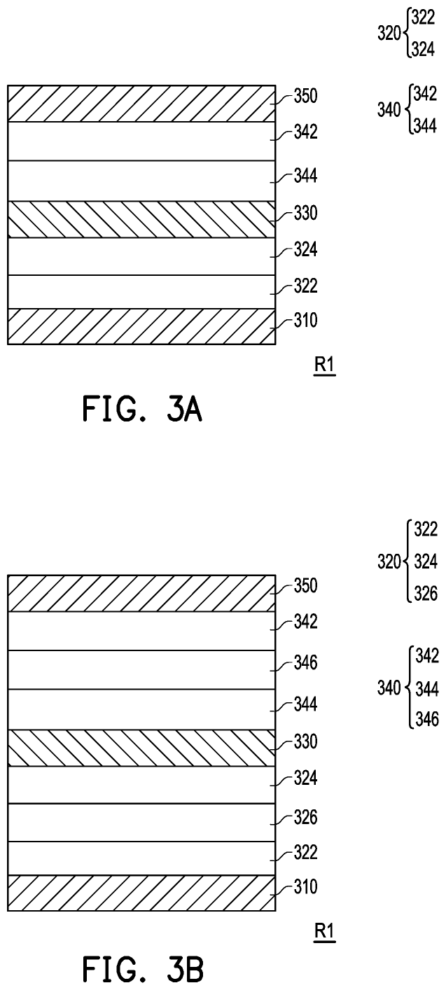

In some embodiments, the composite storage layer 320 and the composite storage layer 340 are respectively a multi-layered structure. The detail configuration of the electrode 310, the composite storage layer 320, the electrode 330, the composite storage layer 340, and the electrode 350 will be discussed below in conjunction with FIG. 3A and FIG. 3B.

FIG. 3A is an enlarged view of a region R1 in FIG. 2C in accordance with some embodiments of the disclosure. Referring to FIG. 3A, the composite storage layer 320 includes a storage layer 322 and a storage layer 324. Meanwhile, the composite storage layer 340 includes a storage layer 342 and a storage layer 344. As illustrated in FIG. 3A, the electrode 310, the storage layer 322, the storage layer 324, the electrode 330, the storage layer 344, the storage layer 342, and the electrode 350 are stacked in sequential order. That is, the composite storage layer 320 is sandwiched between the electrode 310 and the electrode 330, and the composite storage layer 340 is sandwiched between the electrode 330 and the electrode 350.

In some embodiments, the electrodes 310, 330, and 350 may respectively be a single-layered structure or a multi-layered structure. In some embodiments, the electrodes 310, 330, and 350 respectively include various conductive materials, such as a metal, a metal alloy, a metal nitride, a metal silicide, a metal oxide, graphene, or a combination thereof. For example, the electrodes 310, 330, and 350 respectively include aluminum (Al), titanium (Ti), copper (Cu), tungsten (W), platinum (Pt), palladium (Pd), osmium (Os), ruthenium (Ru), tantalum (Ta), or an alloy thereof, titanium nitride (TiN), tantalum nitride (TaN), tungsten nitride (WN), molybdenum nitride (MON), TaSiN, TiSiN, WSiN, tungsten silicide, titanium silicide, cobalt silicide, zirconium silicide, platinum silicide, molybdenum silicide, copper silicide, nickel silicide, indium tin oxide (ITO), iridium oxide (IrO₂), rhenium oxide (ReO₂), rhenium trioxide (ReO₃), or a combination thereof. In some embodiments, the material of the electrodes 310, 330, and 350 may be the same as one another or may be different from one another.

As illustrated in FIG. 3A, the storage layer 322 is in physical contact with the electrode 310. Meanwhile, the storage layer 324 is in physical contact with the electrode 330. Moreover, the storage layer 322 is in physical contact with the storage layer 324. That is, the storage layer 324 is located between the storage layer 322 and the electrode 330. In some embodiments, a conduction band offset (conduction barrier) of the storage layer 322 is different from a conduction band offset of the storage layer 324. Moreover, a dielectric constant (k-value) of the storage layer 322 is also different from a dielectric constant of the storage layer 324. For example, the conduction band offset of the storage layer 322 is greater than the conduction band offset of the storage layer 324, and the dielectric constant of the storage layer 324 is greater than the dielectric constant of the storage layer 322. In order to satisfy the foregoing constraint, a material of the storage layer 322 is different from a material of the storage layer 324. For example, the material of the storage layer 322 includes LaO, AlO, SiO, HfO having a dopant, ZrO having a dopant, or a combination thereof. Meanwhile, the material of the storage layer 324 includes ZrO, HfO, HfZrO, HfO having a dopant, ZrO having a dopant, or a combination thereof. The dopant in the storage layer 322 and the dopant in the storage layer 324 include La, Al, Si, or a combination. In some embodiments, the dopant in the storage layer 322 and the dopant the storage layer 324 are the same. Nevertheless, a doping concentration of the dopant in the storage layer 322 is different form a doping concentration of the dopant in the storage layer 324. For example, the doping concentration of the dopant in the storage layer 322 is greater than the doping concentration of the dopant in the storage 324. However, the disclosure is not limited thereto. In some alternative embodiments, the dopant in the storage layer 322 is different from the dopant in the storage layer 324. It should be noted that the material of the storage layer 322 and the material of the storage layer 324 are not particular limited, as long as the conduction band offset of the storage layer 322 is greater than the conduction band offset of the storage layer 324 and the dielectric constant of the storage layer 324 is greater than the dielectric constant of the storage layer 322.

In some embodiments, the storage layer 342 is in physical contact with the electrode 350. Meanwhile, the storage layer 344 is in physical contact with the electrode 330. Moreover, the storage layer 342 is in physical contact with the storage layer 344. That is, the storage layer 344 is located between the storage layer 342 and the electrode 330. In some embodiments, a conduction band offset of the storage layer 342 is different from a conduction band offset of the storage layer 344. Moreover, a dielectric constant of the storage layer 342 is also different from a dielectric constant of the storage layer 344. For example, the conduction band offset of the storage layer 342 is greater than the conduction band offset of the storage layer 344, and the dielectric constant of the storage layer 344 is greater than the dielectric constant of the storage layer 342. In order to satisfy the foregoing constraint, a material of the storage layer 342 is different from a material of the storage layer 344. In some embodiments, the material of the storage layer 342 and the material of the storage layer 344 are respectively similar to that of the storage layer 322 and the storage layer 324, so the detailed descriptions thereof are omitted herein. It should be noted that the material of the storage layer 342 and the material of the storage layer 344 are not particular limited, as long as the conduction band offset of the storage layer 342 is greater than the conduction band offset of the storage layer 344 and the dielectric constant of the storage layer 344 is greater than the dielectric constant of the storage layer 342.

In some embodiments, during operation of the capacitor 300, unipolar operation voltage is applied to the electrodes 310, 330, and 350. For example, a first voltage is applied to the electrode 310, a second voltage is applied to the electrode 330, and a third voltage is applied to the electrode 350. In some embodiments, the second voltage is greater than the first voltage. Meanwhile, the second voltage is also greater than the third voltage. For example, the first voltage is a negative voltage, the second voltage is a positive voltage, and the third voltage is a negative voltage. That is, the electrode 310 and the electrode 350 are electrically connected to a negative voltage while the electrode 330 is electrically connected to a positive voltage. In some embodiments, since the conduction band offset of the storage layers (i.e., the storage layer 322 and the storage layer 342) contacting the electrodes (i.e., the electrode 310 and the electrode 350) applied with negative voltage is greater than the conduction band offset of the storage layers (i.e., the storage layer 324 and the storage layer 344) contacting the electrode (i.e., the electrode 330) applied with positive voltage, phenomenon of electron tunneling may be sufficiently alleviated, and the leakage of electric current in the capacitor 300 may be sufficient reduced. Moreover, since the dielectric constant of the storage layers (i.e., the storage layer 324 and the storage layer 344) contacting the electrode (i.e., the electrode 330) applied with positive voltage is greater than the dielectric constant of the storage layers (i.e., the storage layer 322 and the storage layer 342) contacting the electrodes (i.e., the electrode 310 and the electrode 350) applied with negative voltage, the overall capacitance of the capacitor 300 may be sufficiently increased. Furthermore, since the material of the storage layer 324 and the storage layer 344 has lower H₂O reactivity, degradation of k-value caused by reaction with H₂O in the ambient environment may be sufficiently suppressed, thereby ensuring the reliability of the capacitor 300.

It should be noted that the detail configuration of the electrode 310, the composite storage layer 320, the electrode 330, the composite storage layer 340, and the electrode 350 in FIG. 3A is merely an exemplary illustration, and the disclosure is not limited thereto. These layers may be arranged in other configurations as shown in FIG. 3B.

FIG. 3B is an enlarged view of a region R1 in FIG. 2C in accordance with some alternative embodiments of the disclosure. Referring to FIG. 3B, the composite storage layer 320 includes a storage layer 322, a storage layer 324, and a blocking layer 326. Meanwhile, the composite storage layer 340 includes a storage layer 342, a storage layer 344, and a blocking layer 346. In some embodiments, the blocking layer 326 is sandwiched between the storage layer 322 and the storage layer 324, and the blocking layer 346 is sandwiched between the storage layer 342 and the storage layer 344. That is, the blocking layer 326 is deposited on the storage layer 322 prior to the deposition of the storage layer 324, and the blocking layer 346 is deposited on the storage layer 344 prior to the deposition of the storage layer 342. As illustrated in FIG. 3B, the electrode 310, the storage layer 322, the blocking layer 326, the storage layer 324, the electrode 330, the storage layer 344, the blocking layer 346, the storage layer 342, and the electrode 350 are stacked in sequential order. That is, the composite storage layer 320 is sandwiched between the electrode 310 and the electrode 330, and the composite storage layer 340 is sandwiched between the electrode 330 and the electrode 350.

In some embodiments, the electrode 310, the storage layer 322, the storage layer 324, the electrode 330, the storage layer 342, the storage layer 344, and the electrode 350 in FIG. 3B are respectively similar to the electrode 310, the storage layer 322, the storage layer 324, the electrode 330, the storage layer 342, the storage layer 344, and the electrode 350 in FIG. 3A, so the detailed descriptions thereof are omitted herein.

In some embodiments, a dielectric constant of the blocking layer 326 is greater than the dielectric constant of the storage layer 322 and the dielectric constant of the storage layer 324. For example, the dielectric constant of the blocking layer 326 is greater than 10. In some embodiments, a crystallinity of the blocking layer 326 is also greater than a crystallinity of the storage layer 322 and a crystallinity of the storage layer 324. In order to satisfy the foregoing constraint, a material of the blocking layer 326 is different from the material of the storage layer 322 and the material of the storage layer 324. For example, the material of the blocking layer 326 includes AlO, Y₂O₃, HfO having a dopant, ZrO having a dopant, or a combination thereof. The dopant in the blocking layer 326 includes La, Al, Si, or a combination. In some embodiments, the dopant in the blocking layer 326 is the same as the dopant in the storage layer 322 and the dopant in the storage layer 324. Nevertheless, a doping concentration of the dopant in the blocking layer 326 is greater than the doping concentration of the dopant in the storage layer 322 and the doping concentration of the dopant in the storage layer 324. However, the disclosure is not limited thereto. In some alternative embodiments, the dopant in the blocking layer 326 is different from the dopant in the storage layer 322 and the dopant in the storage layer 324. It should be noted that the material of the blocking layer 326 is not particular limited, as long as the dielectric constant and the crystallinity of the blocking layer 326 are greater than the dielectric constant and the crystallinity of the storage layer 322 and the dielectric constant and the crystallinity of the storage layer 324.

In some embodiments, a material of the blocking layer 346 is similar to that of the blocking layer 326, so the detailed description thereof is omitted herein. It should be noted that the material of the blocking layer 346 is not particular limited, as long as the dielectric constant and the crystallinity of the blocking layer 346 are greater than the dielectric constant and the crystallinity of the storage layer 342 and the dielectric constant and the crystallinity of the storage layer 344.

In some embodiments, since the blocking layer 326 is sandwiched between the storage layer 322 and the storage layer 324, the blocking layer 326 is able to serve as a crystalline interruption layer for the storage layers 322 and 324. Similarly, since the blocking layer 346 is sandwiched between the storage layer 342 and the storage layer 344, the blocking layer 346 is able to serve as a crystalline interruption layer for the storage layers 342 and 344. That is, the blocking layers 326 and 346 may effectively suppress the storage layers 322, 324, 342, and 344 from crystallization, thereby increasing the overall capacitance of the capacitor 300.

Referring back to FIG. 2D, after the capacitor 300 is formed, a sub-dielectric layer 130 is formed on the capacitor 300. In some embodiments, the sub-dielectric layer 130 is part of one of the dielectric layers 36 of the interconnect structure 30 in FIG. 1. In some embodiments, a material and a formation method of the sub-dielectric layer 130 are similar to that of the sub-dielectric layer 110, so the detailed descriptions thereof are omitted herein. As illustrated in FIG. 2D, the sub-dielectric layer 130 is in physical contact with the electrode 350 and the composite storage layer 340.

Referring to FIG. 2E, a portion of the sub-dielectric layer 120, a portion of the capacitor 300, and a portion of the sub-dielectric layer 130 are removed to form a plurality of openings OP1. For example, the sub-dielectric layer 120, the electrode 310, the composite storage layer 320, the electrode 330, the composite storage layer 340, the electrode 350, and the sub-dielectric layer 130 are patterned by a patterning process to form the openings OP1. The patterning process includes photolithography and one or more etching processes, for example. In some embodiments, the openings OP1 penetrate through the sub-dielectric layer 130, the capacitor 300, and the sub-dielectric layer 120 to expose the underlying conductive patterns 200.

Referring to FIG. 2F, a plurality of conductive features 400 is formed in the openings OP1 and on the sub-dielectric layer 130 to obtain the capacitor structure C1. In some embodiments, each conductive feature 400 includes a conductive via 402 and a conductive line 404 disposed on the conductive via 402. As illustrated in FIG. 2F, the conductive vias 402 fill up the openings OP1. Meanwhile, the conductive lines 404 are disposed on top of the sub-dielectric layer 130. In some embodiments, each of the conductive features 400 includes a seed layer and a metal layer on the seed layer. The seed layer may be a conformal layer lining sidewalls and a bottom surface of the metal layer. In some embodiments, the seed layer may be a single layer or a composite layer including a plurality of sub-layers formed of different materials. For example, the seed layer is a titanium/copper composited layer. The metal layer may include a metal material, such as Al, Cu, W, Co, Pd, Pt, Ni, other low resistivity metal constituent, an alloy thereof, or a combination thereof, and are formed by an electroplating process. In some embodiments, the conductive features 400 are electrically connected to the conductive patterns 34 and the conductive vias 32 of the interconnect structure 30 in FIG. 1.

As illustrated in FIG. 2F, the capacitor 300 is located aside the conductive features 400. For example, the capacitor 300 is located aside the conductive vias 402 of the conductive features 400. In some embodiments, the electrode 310 and the electrode 350 are in physical contact with sidewalls of one of the conductive vias 402. On the other hand, the electrode 330 is in physical contact with sidewalls of another one of the conductive vias 402. Meanwhile, the electrode 310 and the electrode 350 are electrically isolated from the electrode 330. In some embodiments, the capacitor 300 is electrically connected to the conductive patterns 200 through the conductive features 400. That is, the capacitor 300 is connected to the conductive patterns 34 and the conductive vias 32 of the interconnect structure 30 in FIG. 1 through the conductive features 400 and/or the conductive patterns 200.

In some embodiments, since the interconnect structure 30 is being considered as formed during back-end-of-line (BEOL) process, the capacitor structure C1 is also being considered as formed during BEOL processes.

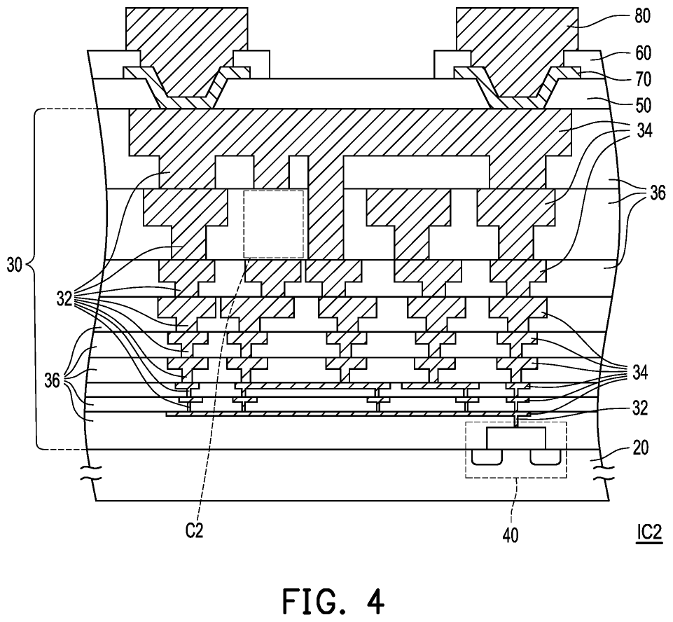

FIG. 4 is a schematic cross-sectional view of an integrated circuit IC2 in accordance with some alternative embodiments of the disclosure. Referring to FIG. 4, the integrated circuit IC2 in FIG. 4 is similar to the integrated circuit IC1 in FIG. 1, so the detailed description thereof is omitted herein. The difference between the integrated circuit IC2 in FIG. 4 and the integrated circuit IC1 in FIG. 1 lies in that the capacitor structure C1 in FIG. 1 is replaced by a capacitor structure C2 in FIG. 4.

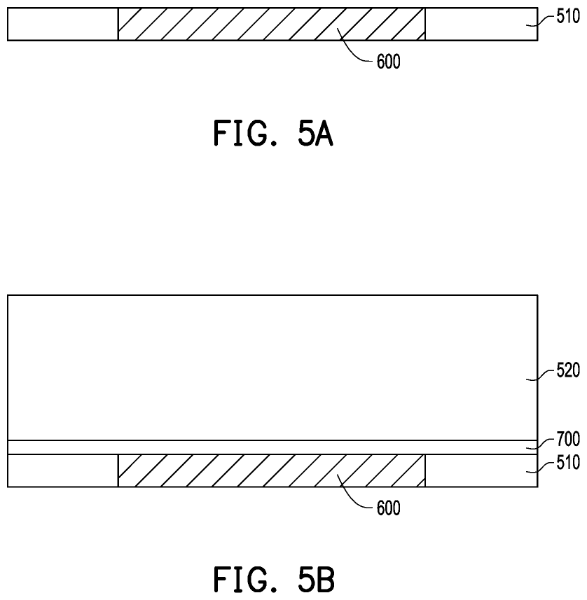

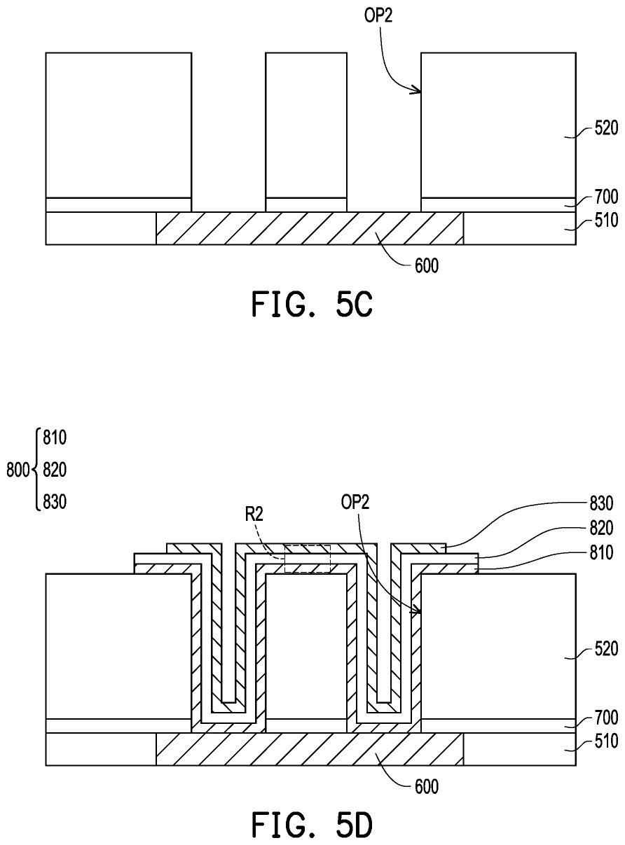

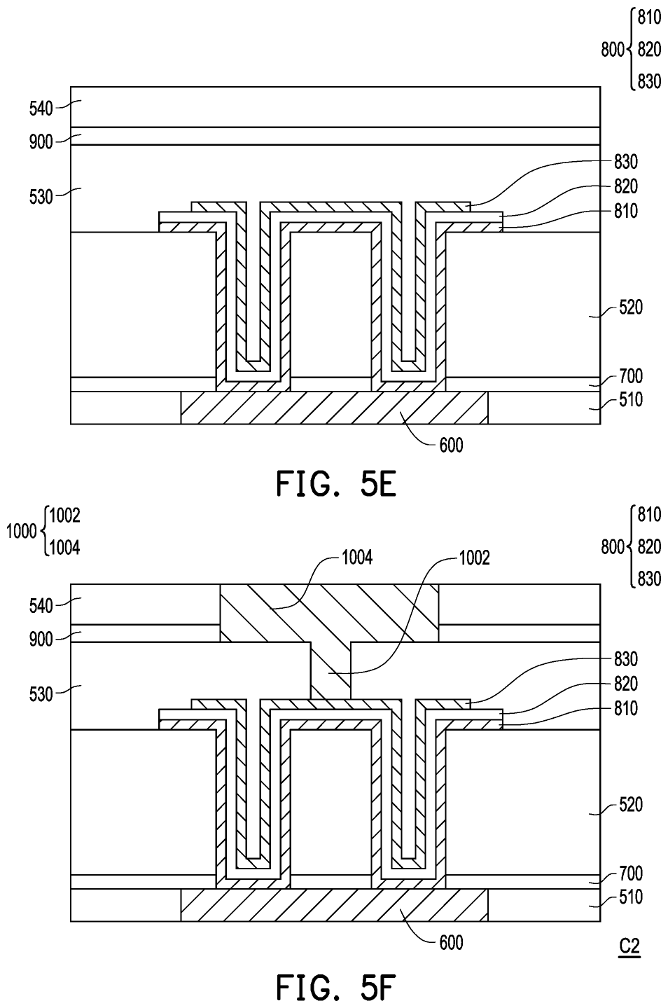

As illustrated in FIG. 4, the capacitor structure C2 is embedded in the interconnect structure 30. For example, the capacitor structure C2 is embedded in one of the dielectric layers 36. In some embodiments, the capacitor structure C2 is electrically connected to the underlying and overlaying conductive vias 32/conductive patterns 34. The formation method and the structure of the capacitor structure C2 will be described below in conjunction with FIG. 5A to FIG. 5F.

FIG. 5A to FIG. 5F are cross-sectional views illustrating various stages of a manufacturing method of the capacitor structure C2 in FIG. 4 in accordance with some embodiments of the disclosure. Referring to FIG. 5A, a sub-dielectric layer 510 is provided. In some embodiments, the sub-dielectric layer 510 is part of one of the dielectric layers 36 of the interconnect structure 30 in FIG. 1, so the detailed description thereof is omitted herein. In some embodiments, a conductive pattern 600 is formed in the sub-dielectric layer 510. For example, the conductive pattern 600 is embedded in the sub-dielectric layer 510. In some embodiments, the conductive pattern 600 is electrically connected to the conductive patterns 34 and the conductive vias 32 of the interconnect structure 30 in FIG. 1. In some embodiments, the conductive pattern 600 includes a seed layer and a metal layer on the seed layer. The seed layer may be a conformal layer lining sidewalls and a bottom surface of the metal layer. In some embodiments, the seed layer may be a single layer or a composite layer including a plurality of sub-layers formed of different materials. For example, the seed layer is a titanium/copper composited layer. The metal layer may include a metal material, such as Al, Cu, W, Co, Pd, Pt, Ni, other low resistivity metal constituent, an alloy thereof, or a combination thereof, and are formed by an electroplating process. As illustrated in FIG. 5A, a top surface of the sub-dielectric layer 510 and a top surface of the conductive pattern 600 are coplanar.

Referring to FIG. 5B, an etch stop layer 700 and a sub-dielectric layer 520 are sequentially formed on the sub-dielectric layer 510 and the conductive pattern 600. In some embodiments, the etch stop layer 700 is in physical contact with the sub-dielectric layer 510 and the conductive pattern 600. For example, the etch stop layer 700 is sandwiched between the sub-dielectric layer 510 and the sub-dielectric layer 520 and is sandwiched between the conductive pattern 600 and the sub-dielectric layer 520. In some embodiments, a material of the etch stop layer 700 includes silicon carbide, silicon nitride, or the like. In some embodiments, the etch stop layer 700 is formed by any suitable method, such as CVD, spin-on coating, or the like. In some embodiments, the sub-dielectric layer 520 is part of one of the dielectric layers 36 of the interconnect structure 30 in FIG. 1. In some embodiments, a material and a formation method of the sub-dielectric layer 520 are similar to that of the sub-dielectric layer 510, so the detailed descriptions thereof are omitted herein.

Referring to FIG. 5C, a portion of the sub-dielectric layer 520 and a portion of the etch stop layer 700 are removed to form a plurality of openings OP2. For example, the sub-dielectric layer 520 and the etch stop layer 700 are patterned by a patterning process to form the openings OP2. The patterning process includes photolithography and one or more etching processes, for example. In some embodiments, the openings OP2 penetrate through the sub-dielectric layer 520 and the etch stop layer 700 to expose the underlying conductive pattern 600.

Referring to FIG. 5D, a capacitor 800 is formed in the openings OP2 and on the sub-dielectric layer 520. In some embodiments, the capacitor 800 includes an electrode 810, a composite storage layer 820, and an electrode 830. In some embodiments, the capacitor 800 is formed by the following steps. First, a first electrode material layer (not shown) is conformally formed on the sub-dielectric layer 520, the etch stop layer 700, and the conductive pattern 600 by a suitable technique such as a PVD process or a plating process. That is, a portion of the first electrode material layer is disposed on a top surface of the sub-dielectric layer 520 while another portion of the first electrode material layer extends into the openings OP2 to be in physical contact with the conductive pattern 600. Thereafter, a composite storage material layer (not shown) is conformally formed on the first electrode material layer. In some embodiments, the composite storage material layer is formed by, for example, CVD, PECVD, FCVD, HDP-CVD, SACVD, PVD, or ALD. In some embodiments, a portion of the composite storage material layer is disposed over the sub-dielectric layer 520 while another portion of the composite storage material layer extends into the openings OP2. Subsequently, a second electrode material layer (not shown) is conformally formed on the composite storage material layer by a suitable technique such as a PVD process or a plating process. In some embodiments, a portion of the second electrode material layer is disposed over the sub-dielectric layer 520 while another portion of the second electrode material layer extends into the openings OP2. Lastly, the first electrode material layer, the composite storage material layer, and the second electrode material layer are patterned by a photolithography and etching process to respectively form the electrode 810, the composite storage layer 820, and the electrode 830. In some embodiments, the electrode 810 and the composite storage layer 820 are patterned by the same photomask. Meanwhile, the electrode 830 is patterned by another photomask. As such, sidewalls of tails of the electrode 810 are aligned with sidewalls of tails of the composite storage layer 820, as shown in FIG. 5D. Meanwhile, sidewalls of tails of the electrode 830 are not aligned with the sidewalls of the tails of the electrode 810 and the sidewalls of the tails of the composite storage layer 820. For example, the electrode 830 exposes a portion of a top surface of the composite storage layer 820.

In some embodiments, the capacitor 800 is partially located in the openings OP2. Therefore, the capacitor 800 may be referred to as a deep trench capacitor (DTC). As illustrated in FIG. 5D, the composite storage layer 820 is in physical contact with both the electrode 810 and the electrode 830 to form a MIM structure. That is, the capacitor 800 may be referred to as a MIM capacitor. In some embodiments, the composite storage layer 820 is utilized to store capacitance.

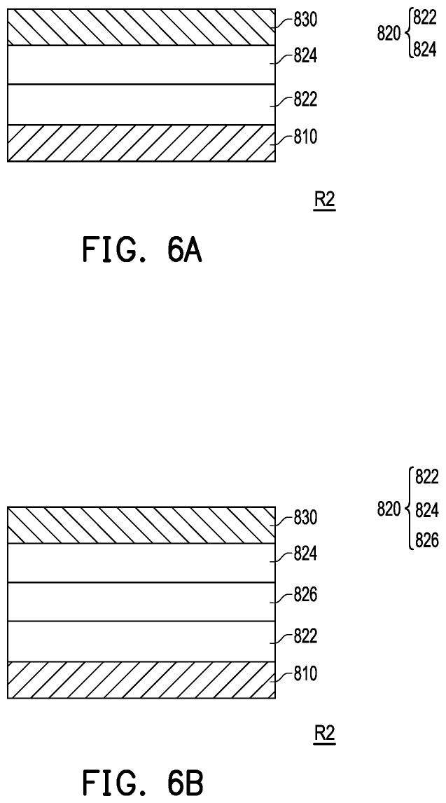

In some embodiments, the composite storage layer 820 is a multi-layered structure. The detail configuration of the electrode 810, the composite storage layer 820, and the electrode 830 will be discussed below in conjunction with FIG. 6A and FIG. 6B.

FIG. 6A is an enlarged view of a region R2 in FIG. 5D in accordance with some embodiments of the disclosure. Referring to FIG. 6A, the composite storage layer 820 includes a storage layer 822 and a storage layer 824. As illustrated in FIG. 6A, the electrode 810, the storage layer 822, the storage layer 824, and the electrode 830 are stacked in sequential order. That is, the composite storage layer 820 is sandwiched between the electrode 810 and the electrode 830.

In some embodiments, the electrodes 810 and 830 may respectively be a single-layered structure or a multi-layered structure. In some embodiments, the electrodes 810 and 830 respectively include various conductive materials, such as a metal, a metal alloy, a metal nitride, a metal silicide, a metal oxide, graphene, or a combination thereof. For example, the electrodes 810 and 830 respectively include aluminum (Al), titanium (Ti), copper (Cu), tungsten (W), platinum (Pt), palladium (Pd), osmium (Os), ruthenium (Ru), tantalum (Ta), or an alloy thereof, titanium nitride (TiN), tantalum nitride (TaN), tungsten nitride (WN), molybdenum nitride (MON), TaSiN, TiSiN, WSiN, tungsten silicide, titanium silicide, cobalt silicide, zirconium silicide, platinum silicide, molybdenum silicide, copper silicide, nickel silicide, indium tin oxide (ITO), iridium oxide (IrO₂), rhenium oxide (ReO₂), rhenium trioxide (ReO₃), or a combination thereof. In some embodiments, the material of the electrodes 810 and 830 may be the same as each other or may be different from each other.

As illustrated in FIG. 6A, the storage layer 822 is in physical contact with the electrode 810. Meanwhile, the storage layer 824 is in physical contact with the electrode 830. Moreover, the storage layer 822 is in physical contact with the storage layer 824. That is, the storage layer 824 is located between the storage layer 822 and the electrode 830. In some embodiments, a conduction band offset of the storage layer 822 is different from a conduction band offset of the storage layer 824. Moreover, a dielectric constant of the storage layer 822 is also different from a dielectric constant of the storage layer 824. For example, the conduction band offset of the storage layer 822 is greater than the conduction band offset of the storage layer 824, and the dielectric constant of the storage layer 824 is greater than the dielectric constant of the storage layer 822. In order to satisfy the foregoing constraint, a material of the storage layer 822 is different from a material of the storage layer 824. For example, the material of the storage layer 822 includes LaO, AlO, SiO, HfO having a dopant, ZrO having a dopant, or a combination thereof. Meanwhile, the material of the storage layer 824 includes ZrO, HfO, HfZrO, HfO having a dopant, ZrO having a dopant, or a combination thereof. The dopant in the storage layer 822 and the dopant in the storage layer 824 include La, Al, Si, or a combination. In some embodiments, the dopant in the storage layer 822 and the dopant in the storage layer 824 are the same. Nevertheless, a doping concentration of the dopant in the storage layer 822 is different form a doping concentration of the dopant in the storage layer 824. For example, the doping concentration of the dopant in the storage layer 822 is greater than the doping concentration of the dopant in the storage 824. However, the disclosure is not limited thereto. In some alternative embodiments, the dopant in the storage layer 822 is different from the dopant in the storage layer 824. It should be noted that the material of the storage layer 822 and the material of the storage layer 824 are not particular limited, as long as the conduction band offset of the storage layer 822 is greater than the conduction band offset of the storage layer 824 and the dielectric constant of the storage layer 824 is greater than the dielectric constant of the storage layer 822.

In some embodiments, during operation of the capacitor 800, unipolar operation voltage is applied to the electrodes 810 and 830. For example, a first voltage is applied to the electrode 810 and a second voltage is applied to the electrode 830. In some embodiments, the second voltage is greater than the first voltage. For example, the first voltage is a negative voltage, and the second voltage is a positive voltage. That is, the electrode 810 is electrically connected to a negative voltage while the electrode 830 is electrically connected to a positive voltage. In some embodiments, since the conduction band offset of the storage layer (i.e., the storage layer 822) contacting the electrode (i.e., the electrode 810) applied with negative voltage is greater than the conduction band offset of the storage layer (i.e., the storage layer 824) contacting the electrode (i.e., the electrode 830) applied with positive voltage, phenomenon of electron tunneling may be sufficiently alleviated, and the leakage of electric current in the capacitor 800 may be sufficient reduced. Moreover, since the dielectric constant of the storage layer (i.e., the storage layer 824) contacting the electrode (i.e., the electrode 830) applied with positive voltage is greater than the dielectric constant of the storage layer (i.e., the storage layer 822) contacting the electrode (i.e., the electrode 810) applied with negative voltage, the overall capacitance of the capacitor 800 may be sufficiently increased. Furthermore, since the material of the storage layer 824 has lower H₂O reactivity, degradation of k-value caused by reaction with H₂O in the ambient environment may be sufficiently suppressed, thereby ensuring the reliability of the capacitor 800.

It should be noted that the detail configuration of the electrode 810, the composite storage layer 820, and the electrode 830 in FIG. 6A is merely an exemplary illustration, and the disclosure is not limited thereto. These layers may be arranged in other configurations as shown in FIG. 6B.

FIG. 6B is an enlarged view of a region R2 in FIG. 5D in accordance with some alternative embodiments of the disclosure. Referring to FIG. 6B, the composite storage layer 820 includes a storage layer 822, a storage layer 824, and a blocking layer 826. In some embodiments, the blocking layer 826 is sandwiched between the storage layer 822 and the storage layer 824. That is, the blocking layer 826 is deposited on the storage layer 822 prior to the deposition of the storage layer 824. As illustrated in FIG. 6B, the electrode 810, the storage layer 822, the blocking layer 826, the storage layer 824, and the electrode 830 are stacked in sequential order. That is, the composite storage layer 820 is sandwiched between the electrode 810 and the electrode 830.

In some embodiments, the electrode 810, the storage layer 822, the storage layer 824, and the electrode 830 in FIG. 6B are respectively similar to the electrode 810, the storage layer 822, the storage layer 824, and the electrode 830 in FIG. 6A, so the detailed descriptions thereof are omitted herein.

In some embodiments, a dielectric constant of the blocking layer 826 is greater than the dielectric constant of the storage layer 822 and the dielectric constant of the storage layer 824. For example, the dielectric constant of the blocking layer 826 is greater than 10. In some embodiments, a crystallinity of the blocking layer 826 is also greater than a crystallinity of the storage layer 822 and a crystallinity of the storage layer 824. In order to satisfy the foregoing constraint, a material of the blocking layer 826 is different from the material of the storage layer 822 and the material of the storage layer 824. For example, the material of the blocking layer 826 includes AlO, Y₂O₃, HfO having a dopant, ZrO having a dopant, or a combination thereof. The dopant in the blocking layer 826 includes La, Al, Si, or a combination. In some embodiments, the dopant in the blocking layer 826 is the same as the dopant in the storage layer 822 and the dopant in the storage layer 824. Nevertheless, a doping concentration of the dopant in the blocking layer 826 is greater than the doping concentration of the dopant in the storage layer 822 and the doping concentration of the dopant in the storage layer 824. However, the disclosure is not limited thereto. In some alternative embodiments, the dopant in the blocking layer 826 is different from the dopant in the storage layer 822 and the dopant in the storage layer 824. It should be noted that the material of the blocking layer 826 is not particular limited, as long as the dielectric constant and the crystallinity of the blocking layer 826 is greater than the dielectric constant and the crystallinity of the storage layer 822 and the dielectric constant and the crystallinity of the storage layer 824.

In some embodiments, since the blocking layer 826 is sandwiched between the storage layer 822 and the storage layer 824, the blocking layer 826 is able to serve as a crystalline interruption layer for the storage layers 822 and 824. That is, the blocking layer 826 may effectively suppress the storage layers 822 and 824 from crystallization, thereby increasing the overall capacitance of the capacitor 800.

Referring back to FIG. 5E, after the capacitor 800 is formed, a sub-dielectric layer 530, an etch stop layer 900, and a sub-dielectric layer 540 are sequentially formed on the capacitor 800 and the sub-dielectric layer 520. In some embodiments, the sub-dielectric layer 530 and the sub-dielectric layer 540 are part of one of the dielectric layers 36 of the interconnect structure 30 in FIG. 1. In some embodiments, materials and a formation methods of the sub-dielectric layer 530 and the sub-dielectric layer 540 are similar to that of the sub-dielectric layer 510, so the detailed descriptions thereof are omitted herein. As illustrated in FIG. 5E, the sub-dielectric layer 530 is in physical contact with the capacitor 800. For example, the sub-dielectric layer 530 is in physical contact with the electrode 810, the composite storage layer 820, and the electrode 830.

In some embodiments, the etch stop layer 900 is sandwiched between the sub-dielectric layer 530 and the sub-dielectric layer 540. In some embodiments, a material of the etch stop layer 900 includes silicon carbide, silicon nitride, or the like. In some embodiments, the etch stop layer 900 is formed by any suitable method, such as CVD, spin-on coating, or the like.

Referring to FIG. 5F, a conductive feature 1000 is formed in the sub-dielectric layer 530, the etch stop layer 900, and the sub-dielectric layer 540 to obtain the capacitor structure C2. In some embodiments, the conductive feature 1000 includes a conductive via 1002 and a conductive line 1004 disposed on the conductive via 1002. As illustrated in FIG. 5F, the conductive via 1002 is embedded in the sub-dielectric layer 530. Meanwhile, the conductive line 1004 is embedded in the etch stop layer 900 and the sub-dielectric layer 540. In some embodiments, the conductive feature 1000 includes a seed layer and a metal layer on the seed layer. The seed layer may be a conformal layer lining sidewalls and a bottom surface of the metal layer. In some embodiments, the seed layer may be a single layer or a composite layer including a plurality of sub-layers formed of different materials. For example, the seed layer is a titanium/copper composited layer. The metal layer may include a metal material, such as Al, Cu, W, Co, Pd, Pt, Ni, other low resistivity metal constituent, an alloy thereof, or a combination thereof, and are formed by an electroplating process. In some embodiments, the conductive feature 1000 is electrically connected to the conductive patterns 34 and the conductive vias 32 of the interconnect structure 30 in FIG. 1.

As illustrated in FIG. 5F, the conductive via 1002 of the conductive feature 1000 is in physical contact with the capacitor 800. For example, the conductive via 1002 of the conductive feature 1000 is in physical contact with the electrode 830. As such, the conductive feature 1000 is electrically connected to the capacitor 800. Moreover, the capacitor 800 is in physical contact with the conductive pattern 600. For example, the electrode 810 is in physical contact with the conductive pattern 600. As such, the conductive pattern 600 is electrically connected to the capacitor 800. That is, the capacitor 800 is connected to the conductive patterns 34 and the conductive vias 32 of the interconnect structure 30 in FIG. 1 through the conductive feature 1000 and/or the conductive pattern 600.

In some embodiments, since the interconnect structure 30 is being considered as formed during back-end-of-line (BEOL) process, the capacitor structure C2 is also being considered as formed during BEOL processes.

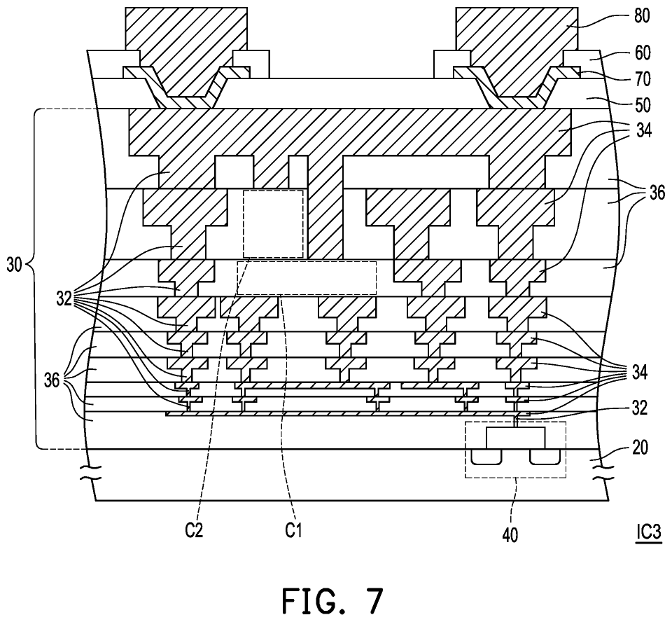

FIG. 7 is a schematic cross-sectional view of an integrated circuit IC3 in accordance with some alternative embodiments of the disclosure.

Referring to FIG. 7, the integrated circuit IC3 in FIG. 7 is similar to the integrated circuit IC1 in FIG. 1, so the detailed description thereof is omitted herein. The difference between the integrated circuit IC3 in FIG. 7 and the integrated circuit IC1 in FIG. 1 lies in that the integrated circuit IC3 in FIG. 7 further includes a capacitor structure C2. As illustrated in FIG. 7, the capacitor structure C2 is embedded in the interconnect structure 30. For example, the capacitor structure C2 is embedded in one of the dielectric layers 36. In some embodiments, the capacitor structure C2 is electrically connected to the underlying and overlaying conductive vias 32/conductive patterns 34. As illustrated in FIG. 7, the capacitor structure C2 is disposed on top of the capacitor structure C1. In some embodiments, the capacitor structure C1 and the capacitor structure C2 are embedded in different dielectric layers 36. In some embodiments, the capacitor structure C2 in FIG. 7 may be similar to the capacitor structure C2 in FIG. 4 and FIG. 5F, so the detailed description thereof is omitted herein. As mentioned above, the capacitor structure C1 includes the capacitor 300 and the capacitor structure C2 includes the capacitor 800. As such, the capacitor 300 in FIG. 2F and the capacitor 800 in FIG. 5F coexist in the integrated circuit IC3. For example, the capacitor 800 is disposed over the capacitor 300.

In some embodiments, since the interconnect structure 30 is being considered as formed during back-end-of-line (BEOL) process, the capacitor structure C1 and the capacitor structure C2 are also being considered as formed during BEOL processes.

In accordance with some embodiments of the disclosure, a capacitor includes a first electrode, a second electrode over the first electrode, and a composite storage layer sandwiched between the first electrode and the second electrode. The composite storage layer includes a first storage layer and a second storage layer. The first storage layer is in physical contact with the first electrode. The second storage layer is in physical contact with the second electrode. A conduction band offset of the first storage layer is greater than a conduction band offset of the second storage layer, and a dielectric constant of the second storage layer is greater than a dielectric constant of the first storage layer.

In accordance with some embodiments of the disclosure, an integrated circuit includes a substrate, a transistor, and an interconnect structure. The transistor is over the substrate. The interconnect structure is disposed on the substrate and includes dielectric layers and a first capacitor. The first capacitor is embedded in the dielectric layers. The first capacitor includes a first electrode, a first storage layer, a second electrode, and a second storage layer. The first storage layer is on the first electrode. The second electrode is over the first storage layer. The second storage layer is between the first storage layer and the second electrode. A material of the first storage layer is different from a material of the second storage layer.

In accordance with some embodiments of the disclosure, a manufacturing method of an integrated circuit includes at least the following steps. A substrate is provided. A transistor is formed over the substrate. An interconnect structure is formed over the substrate. The interconnect structure is formed by at least the following steps. First, dielectric layers are formed. Thereafter, a capacitor is formed in the dielectric layers. The capacitor is formed by at least the following steps. A first electrode is deposited. A composite storage layer is formed on the first electrode. A second electrode is deposited on the composite storage layer. The composite storage layer is formed by at least the following steps. A first storage layer is deposited on the first electrode. A second storage layer is deposited over the first storage layer. A material of the first storage layer is different from a material of the second storage layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A capacitor, comprising:
a first electrode;
a second electrode over the first electrode; and
a composite storage layer sandwiched between the first electrode and the second electrode, comprising:
a first storage layer in physical contact with the first electrode; and
a second storage layer in physical contact with the second electrode, wherein a conduction band offset of the first storage layer is greater than a conduction band offset of the second storage layer, and a dielectric constant of the second storage layer is greater than a dielectric constant of the first storage layer.

2. The capacitor of claim 1, wherein a first voltage is applied to the first electrode, a second voltage is applied to the second electrode, and the second voltage is greater than the first voltage.

3. The capacitor of claim 2, wherein the first voltage is a negative voltage and the second voltage is a positive voltage.

4. The capacitor of claim 1, wherein a material of the first storage layer comprises LaO, AlO, SiO, HfO having a dopant, ZrO having a dopant, or a combination thereof.

5. The capacitor of claim 4, wherein a material of the second storage layer comprises ZrO, HfO, HfZrO, HfO having a dopant, ZrO having a dopant, or a combination thereof.

6. The capacitor of claim 5, wherein the dopant in the first storage layer and the dopant in the second storage layer respectively comprise La, Al, Si, or a combination thereof.

7. The capacitor of claim 5, wherein a doping concentration of the dopant in the first storage layer is greater than a doping concentration of the dopant in the second storage layer.

8. The capacitor of claim 1, wherein the composite storage layer further comprises a blocking layer sandwiched between the first storage layer and the second storage layer.

9. The capacitor of claim 8, wherein a material of the blocking layer comprise AlO, Y₂O₃, HfO having a dopant, ZrO having a dopant, or a combination thereof.

10. An integrated circuit, comprising:
a substrate;
a transistor over the substrate; and
an interconnect structure disposed on the substrate, comprising;
dielectric layers; and
a first capacitor embedded in the dielectric layers, comprising:
a first electrode;
a first storage layer on the first electrode;
a second electrode over the first storage layer; and
a second storage layer between the first storage layer and the second electrode, wherein a material of the first storage layer is different from a material of the second storage layer.

11. The integrated circuit of claim 10, wherein a conduction band offset of the first storage layer is greater than a conduction band offset of the second storage layer, and a dielectric constant of the second storage layer is greater than a dielectric constant of the first storage layer.

12. The integrated circuit of claim 10, wherein a negative voltage is applied to the first electrode and a positive voltage is applied to the second electrode.

13. The integrated circuit of claim 10, wherein a material of the first storage layer comprises LaO, AlO, SiO, HfO having a dopant, ZrO having a dopant, or a combination thereof, and a material of the second storage layer comprises ZrO, HfO, HfZrO, HfO having a dopant, ZrO having a dopant, or a combination thereof.

14. The integrated circuit of claim 13, wherein the dopant in the first storage layer and the dopant in the second storage layer respectively comprise La, Al, Si, or a combination thereof.

15. The integrated circuit of claim 10, wherein the first capacitor further comprises a blocking layer sandwiched between the first storage layer and the second storage layer.

16. The integrated circuit of claim 15, wherein a material of the blocking layer comprise AlO, Y₂O₃, HfO having a dopant, ZrO having a dopant, or a combination thereof.

17. The integrated circuit of claim 10, wherein the interconnect structure further comprises a second capacitor over the first capacitor and embedded in the dielectric layers, and the second capacitor comprises:
a third electrode;
a third storage layer on the third electrode;
a fourth electrode over the third storage layer; and
a fourth storage layer between the third storage layer and the fourth electrode, wherein a conduction band offset of the third storage layer is greater than a conduction band offset of the fourth storage layer, and a dielectric constant of the fourth storage layer is greater than a dielectric constant of the third storage layer.

18. A manufacturing method of an integrated circuit, comprising:
providing a substrate;
forming a transistor over the substrate; and
forming an interconnect structure over the substrate, comprising:
forming dielectric layers; and
forming a capacitor in the dielectric layers, comprising:
depositing a first electrode;
forming a composite storage layer on the first electrode, comprising:
depositing a first storage layer on the first electrode; and
depositing a second storage layer over the first storage layer, wherein a material of the first storage layer is different from a material of the second storage layer; and
depositing a second electrode on the composite storage layer.

19. The method of claim 18, wherein a conduction band offset of the first storage layer is greater than a conduction band offset of the second storage layer, and a dielectric constant of the second storage layer is greater than a dielectric constant of the first storage layer.

20. The method of claim 18, wherein forming the composite storage layer further comprises:
depositing a blocking layer on the first storage layer prior to the deposition of the second storage layer.
